(19) United States
(12) Patent Application Publication
(10) Pub. No.: US 2025/0293185 A1
(43) Pub. Date: Sep. 18, 2025

(54) SEMICONDUCTOR PACKAGE

(71) Applicant: Samsung Electronics Co., Ltd., Suwon-si (KR)

(72) Inventor: Youngja KIM, Suwon-si (KR)

(73) Assignee: Samsung Electronics Co., Ltd., Suwon-si (KR)

(21) Appl. No.: 18/898,790

(22) Filed: Sep. 27, 2024

(30) Foreign Application Priority Data
Mar. 14, 2024 (KR) 10-2024-0035764

(51) Int. Cl. H01L 23/00; H01L 23/31; H01L 25/18; H10B 80/00

(52) U.S. Cl. CPC H01L 24/05; H01L 23/3128; H01L 23/3135; H01L 24/06; H01L 24/16; H01L 24/17; H01L 24/32; H01L 24/48; H01L 24/73; H01L 24/81; H01L 24/83; H01L 25/18; H01L 2224/05553; H01L 2224/05558; H01L 2224/05568; H01L 2224/0603; H01L 2224/06051; H01L 2224/06102; H01L 2224/06183; H01L 2224/16013; H01L 2224/16145; H01L 2224/16227; H01L 2224/16238; H01L 2224/17133; H01L 2224/32058; H01L 2224/32059; H01L 2224/3207; H01L 2224/32145; H01L 2224/32225; H01L 2224/4807; H01L 2224/48091; H01L 2224/48147; H01L 2224/48229; H01L 2224/73204; H01L 2224/73207; H01L 2224/73215; H01L 2224/73265; H01L 2224/81203; H01L 2224/8121; H01L 2224/83203; H01L 2224/8321; H01L 2225/06506; H01L 2225/0651; H01L 2225/06513; H01L 2225/06517; H01L 2924/381; H01L 2924/3841; H01L 2924/386; H10B 80/00

(57) ABSTRACT

A semiconductor package may include an interconnection structure in which at least one insulating layer and at least one interconnection layer are alternately stacked, a semiconductor chip including a plurality of pads, the semiconductor chip at least partially overlapping with the interconnection structure in the vertical direction, a plurality of bumps between the plurality of pads and the interconnection structure, a peripheral pad portion at least a portion of which on a side surface of the semiconductor chip and electrically connected to the semiconductor chip by a surface thereof that opposing the semiconductor chip, and a peripheral connection portion electrically connecting the peripheral pad portion and the interconnection structure to each other.

### CROSS-REFERENCE TO RELATED APPLICATION(S)

This application claims benefit of priority to Korean Patent Application No. 10-2024-0035764 filed on Mar. 14, 2024 in the Korean Intellectual Property Office, the disclosure of which is incorporated herein by reference in its entirety.

### BACKGROUND

The present inventive concepts relate to a semiconductor package.

Semiconductor chips may be mounted on a substrate through various types of bumps. A semiconductor chip may receive power from a substrate and/or transmit a signal to the substrate through a plurality of bumps, thereby providing electrical connection paths. For example, semiconductor chips may be implemented to have high performance and/or a high degree of integration, such that a plurality of bumps, connected to the semiconductor chips, may be arranged at a finer pitch.

### SUMMARY

The present inventive concepts relate to a semiconductor package capable of efficiently increasing the number of electrical connection paths that may be provided by a semiconductor chip or chips.

According to some example embodiments of inventive concepts, a semiconductor package may include an interconnection structure in which at least one insulating layer and at least one interconnection layer are alternately stacked; a semiconductor chip including a plurality of pads, the semiconductor chip at least partially overlapping with the interconnection structure in the vertical direction; a plurality of bumps between the plurality of pads and the interconnection structure; a peripheral pad portion at least a portion of which is on a side surface of the semiconductor chip, the peripheral pad portion being electrically connected to the semiconductor chip by a surface thereof that is opposing the semiconductor chip; and a peripheral connection portion electrically connecting the peripheral pad portion and the interconnection structure to each other.

According to some example embodiments aspect of the present inventive concepts, a semiconductor package may include an interconnection structure in which at least one insulating layer and at least one interconnection layer are alternately stacked; a semiconductor chip including a plurality of pads, the semiconductor chip at least partially overlapping with the interconnection structure in the vertical direction; a plurality of bumps between the plurality of pads and the interconnection structure; an underfill portion between the interconnection structure and the semiconductor chip, the underfill portion at least partially surrounding the plurality of bumps; and a peripheral connection portion extending along a surface of the underfill portion and from a position lower than that of an upper surface of the semiconductor chip to the interconnection structure, and electrically connect the semiconductor chip and the interconnection structure to each other.

According to some example embodiments of the present inventive concepts, a semiconductor package may include an interconnection structure in which at least one insulating layer and at least one interconnection layer are alternately stacked; a semiconductor chip including a plurality of pads, the semiconductor chip at least partially overlapping with the interconnection structure in the vertical direction; a plurality of bumps between the plurality of pads and the interconnection structure; an underfill portion between the interconnection structure and the semiconductor chip, the underfill portion at least partially surrounding the plurality of bumps; and a peripheral connection portion extending along a surface of the underfill portion and from a position lower than that of an upper surface of the semiconductor chip to the interconnection structure, and electrically connect the semiconductor chip and the interconnection structure to each other.

### BRIEF DESCRIPTION OF DRAWINGS

The above and other aspects, features, and advantages of the present inventive concepts will be more clearly understood from the following detailed description, taken in conjunction with the accompanying drawings, in which:

FIGS. 1A to 1D are cross-sectional views of a semiconductor package according to some example embodiments of the present inventive concepts;

FIGS. 2A to 2C are plan views of a semiconductor package according to some example embodiments of the present inventive concepts;

FIGS. 3A to 3G are diagrams of a method of manufacturing a semiconductor package according to some example embodiments of the present inventive concepts; and

FIGS. 4 to 6 are cross-sectional views of a semiconductor package according to some example embodiments of the present inventive concepts.

### DETAILED DESCRIPTION

The detailed description of the present inventive concepts to be described later refers to the accompanying drawings which, by way of example, illustrate example embodiments by which the present inventive concepts may be practiced. These example embodiments are described in sufficient detail to enable one ordinarily skilled in the art to practice the present inventive concepts. It should be understood that the various example embodiments of the present inventive concepts may be different from each other but are not necessarily mutually exclusive. For example, some example embodiments of specific shapes, structures, and characteristics described herein may be implemented in another example embodiment without departing from the spirit and scope of the present inventive concepts. Additionally, it should be understood that the location or arrangement of individual components within each example embodiment may be changed without departing from the spirit and scope of the present inventive concepts. Accordingly, the detailed description set forth below is not intended to be taken in a limiting sense, and the scope of the present inventive concepts is limited only by the appended claims, with all equivalents as claimed by those claims. Like reference numbers in the drawings indicate the same or similar function throughout the various aspects.

Hereinafter, example embodiments of the present inventive concepts will be described in detail with reference to the accompanying drawings such that those ordinarily skilled in the art may easily practice the present inventive concepts.

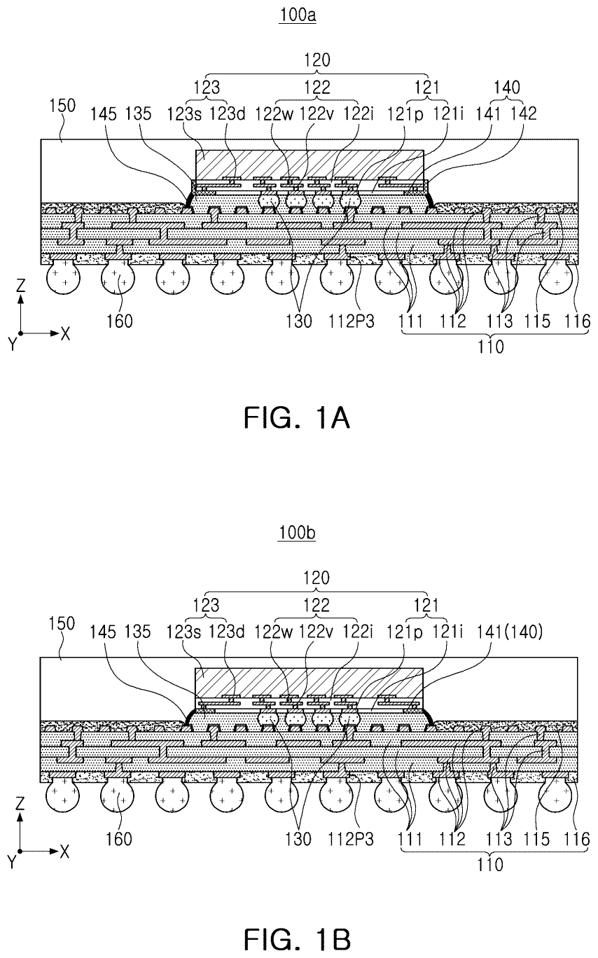

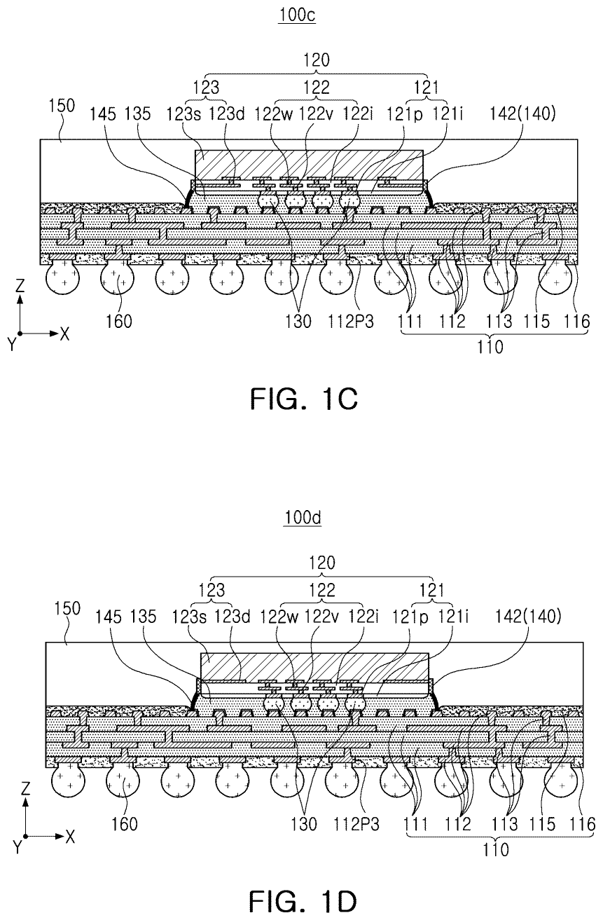

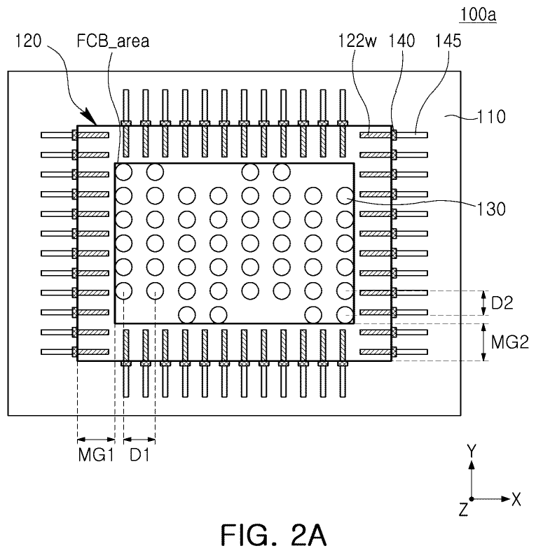

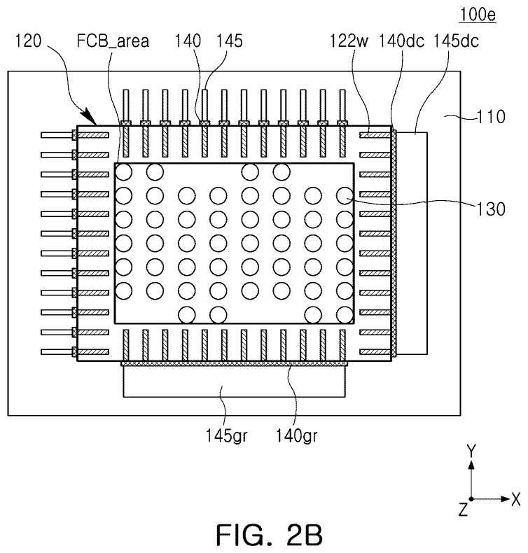

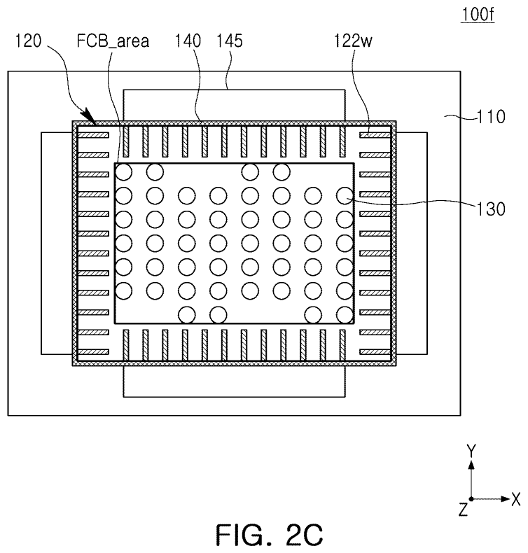

FIG. 1A illustrates a cross-section of a semiconductor package 100a taken on an X-Z plane according to some example embodiments of the present inventive concepts, and FIG. 2A is a cross-sectional view of the semiconductor package 100a in which some structures are disposed on an X-Y plane. Referring to FIGS. 1A and 2A, the semiconductor package 100a according to some example embodiments of the present inventive concepts may include an interconnection structure 110, a semiconductor chip 120, a plurality of bumps 130, a peripheral pad portion 140, and a peripheral connection portion 145.

The interconnection structure 110 may have a structure in which at least one insulating layer 111 and at least one interconnection layer 112 are alternately stacked. For example, the interconnection structure 110 may be or include a support substrate on which the semiconductor chip 120 is mounted, and/or may be or include a package substrate for interconnecting a plurality of pads 121p of the semiconductor chip 120. The package substrate may, for example, include a printed circuit board (PCB), a ceramic substrate, a glass substrate, a tape interconnection substrate, or the like, but example embodiments are not limited thereto. The interconnection structure 110 may include, for example, insulating layers 111, interconnection layers 112, interconnection vias 113, an upper solder mask layer 115, and a lower solder mask layer 116. In example embodiments, the number of insulating layers 111 and interconnection layers 112 included in the interconnection structure 110 may be changed in various manners. In some example embodiments, the interconnection structure 110 may, for example, be or include an interposer substrate, for example, an organic interposer. In some example embodiments, the interconnection structure 110 may be or include a module substrate. In such case, the semiconductor chip 120 may be or include a semiconductor structure such as a semiconductor package, but example embodiments are not limited thereto.

The insulating layers 111 include an insulating material and may include, for example, a thermosetting resin such as an epoxy resin or a thermoplastic resin such as polyimide. For example, the insulating layers 111 may include a photosensitive insulating material such as a photoimageable dielectric (PID) resin. Alternatively, or additionally, the insulating layers 111 may include a resin mixed with an inorganic filler, for example, an Ajinomoto Build-up Film (ABF). Alternatively, or additionally, the insulating layers 111 may include, for example, a prepreg, flame retardant (FR-4), or bismaleimide triazine (BT). The insulating layers 111 may individually include the same material or different materials. Depending on materials and/or a processes of each of the insulating layers 111, the insulating layers 111 may or may not be distinguished from each other in terms of a boundary therebetween.

Any or each of the interconnection layers 112 may include at least one interconnection line and/or redistribution line. The interconnection layers 112 and interconnection vias 113 may form an electrical path. The interconnection layers 112 and the interconnection vias 113 may interconnect the semiconductor chip 120 to a region outside of the semiconductor chip 120, for example, a fan-out region not overlapping with the semiconductor chip 120 in a Z-direction. Accordingly, the semiconductor package 100a according to the some example embodiments may include or be referred to as a fan-out semiconductor package. However, the semiconductor package is not limited thereto. In some example embodiments, the semiconductor package 100a may include or form a fan-in semiconductor package. The interconnection layers 112 and the interconnection vias 113 may include, for example, a ground pattern, a power pattern, and/or a signal pattern. The interconnection layers 112 may be disposed on the X-Y plane to have a linear or substantially linear shape, and the interconnection vias 113 may have a cylindrical or substantially cylindrical shape having an inclined side surface having an upwardly or downwardly decreasing width. The interconnection vias 113 are illustrated as filled vias, entirely filled with a conductive material, but the interconnection vias 113 are not limited thereto. For example, one or more of the interconnection vias 113 may be in the form of a conformal via(s) in which, for example, a metal material is formed along an inner wall of a via hole.

The interconnection layers 112 and/or the interconnection vias 113 may include, for example, a conductive material, for example, copper (Cu), aluminum (Al), silver (Ag), tin (Sn), gold (Au), nickel (Ni), lead (Pb), titanium (Ti), or any alloys thereof. Depending on a width of an interconnection line of the interconnection layers 112 or a distance (for example, 10 μm or about 10 μm to 100 μm or about 100 μm) between interconnection lines, an interconnection line of the interconnection layers 112 may be implemented as a redistribution line. FIG. 1A illustrates an interconnection structure 110, implemented as a protruded trace substrate (PTS) having a structure in which an uppermost interconnection layer and a lowermost interconnection layer, among the interconnection layers 112, vertically protrude, respectively, from an uppermost insulating layer and a lowermost insulating layer, among the insulating layers 111. However, the interconnection structure 110 may be or include, for example, an embedded trace substrate (ETS) depending on a design thereof.

The interconnection layers 112 may include a plurality of lower pads 112P3 any of each of which may be, for example, exposed through a lower solder mask layer 116. The plurality of lower pads 112P3 may be disposed on a lowermost insulating layer, among the insulating layers 111, and may be, for example, downwardly exposed through a plurality of upper and lower passages of the lower solder mask layer 116 to be electrically connected to a plurality of package bumps 160. Each of the plurality of lower pads 112P3 may have upper and lower surfaces having, for example, a circular, polygonal, or substantially similar shape. As a diameter of each of the plurality of package bumps 160 increases, a width of each of the plurality of lower pads 112P3 may also increase.

The upper and lower solder mask layers 115 and 116 of the interconnection structure 110 may be, for example, solder resist layers, to protect the interconnection layer 112 from, for example, external physical and/or chemical damage. The upper and lower solder mask layers 115 and 116 may include, for example, an insulating material, and may include, for example, a prepreg, an ABF, FR-4, BT, and/or a photo solder resist (PSR), but example embodiments are not limited thereto.

The semiconductor chip 120 may be disposed to vertically overlap the interconnection structure 110. The semiconductor chip 120 may include a plurality of pads 121p on a lower surface thereof. The semiconductor chip 120 may be mounted on an upper surface of the interconnection structure 110 using a flip-chip bonding method (for example, disposed in a flip-chip manner). The semiconductor chip 120 may include an element layer 123d positioned in a lower portion thereof on which the plurality of pads 121p are disposed, and/or on which an integrated circuit (IC) is disposed. The semiconductor chip 120 may include, for example, a logic semiconductor chip and/or a memory semiconductor chip. The logic semiconductor chip may be or include a microprocessor, for example, a central processing unit (CPU), a graphics processing unit (GPU), a field programmable gate array (FPGA), an application processor (AP), a digital signal processor, a cryptographic processor, a controller, and/or an application specific integrated circuit (ASIC). The memory semiconductor chip may be, for example, a volatile memory such as dynamic random access memory (DRAM), static random access memory (SRAM), or the like, or a non-volatile memory such as flash memory or the like. However, example embodiments are not limited thereto.

For example, the semiconductor chip 120 may include a pad layer 121, a device layer 122, and a semiconductor substrate 123. The pad layer 121 may include a plurality of pads 121p and a passivation layer 121i, and the device layer 122 may include a chip interconnection layer 122w, chip interconnection vias 122v, and a chip insulation layer 122i. The semiconductor substrate 123 may include an element layer 123d and a body portion 123s.

The semiconductor substrate 123 may be disposed above the pad layer 121 and the device layer 122. The body portion 123s of the semiconductor substrate 123 may include, for example, a semiconductor material such as, for example, silicon. For example, the semiconductor substrate 123 may include various impurity regions for an individual element, and/or may include an element isolation structure such as a shallow trench isolation (STI) structure. The semiconductor material, however, is not limited to silicon, and may include, for example, at least one of germanium, silicon carbide (SiC), gallium arsenide (GaAs), indium arsenide (InAs), and indium phosphide (InP), but example embodiments are not limited thereto. For example, an element of the element layer 123d may include, for example, a planar metal oxide semiconductor FET (MOSFET), a FinFET having an active region as a fin structure, a multi bridge channel FET (MBCFET™) or gate-all-around transistor including a plurality of channels vertically stacked on an active region thereof, and/or a vertical FET (VFET), but the present inventive concept is not limited thereto.

The device layer 122 may be disposed between the semiconductor substrate 123 and the pad layer 121. The device layer 122 may include an interconnection structure connected to the element layer 123d. The interconnection structure may have a structure in which at least one chip interconnection layer 122w is stacked in the Z-direction and disposed on the X-Y plane to have a linear or substantially linear shape, and may include chip interconnection vias 122v, which may connect chip interconnection layers 122w to each other in the Z-direction. Each of the chip interconnection layer 122w and the chip interconnection vias 122v may include, for example, at least one metal material, for example, copper (Cu), an copper alloy, aluminum (Al), and an aluminum alloy. However, metal material is not limited thereto, and may be or include, for example, at least one of nickel (Ni), gold (Au), cobalt (Co), tantalum (Ta), tellurium (Te), titanium (Ti), tungsten (W), and any alloys thereof (for example, TiN and TaN). A space of (for example, defined by) the device layer 122 in which the chip interconnection layer 122w and the chip interconnection vias 122v are not disposed may be filled with a chip insulating layer 122i. For example, the insulating layer 122i may include, for example, at least one of silicon oxide (SiO), silicon nitride (SiN), silicon oxynitride (SiON), silicon oxycarbide (SiOC), and silicon carbonitride (SiCN), but example embodiments are not limited thereto.

The pad layer 121 may be disposed below the device layer 122 and the semiconductor substrate 123. The plurality of pads 121p of the pad layer 121 may be or include, for example, pads of a bare chip, for example, aluminum (Al) pads, and/or may be or include pads of a packaged chip, for example, copper (Cu) pads in some example embodiments, but example embodiments are not limited thereto. The plurality of pads 121p may be electrically connected to the interconnection layer 112 of the interconnection structure 110 through a plurality of chip bumps 130. Being electrically connected may be understood as providing at least a portion of a path through which a signal is transmitted. In some example embodiments, a passivation layer 121i, exposing the plurality of pads 121p, may be further disposed on a lower surface of the semiconductor chip 120. The passivation layer 121i may surround or at least partially surround any or each of the plurality of pads 121p. The passivation layer 121i may include, for example, one or more silicon oxide film and/or a silicon nitride films. For example, each of the passivation layers 121i may include at least one of SiO₂, SiN, SiCN, and tetraethyloxysilane (TEOS), but example embodiments are not limited thereto.

The plurality of bumps 130 may be disposed between the plurality of pads 121p and the interconnection structure 110, and may electrically connect the interconnection layer 112 of the interconnection structure 110 and the plurality of pads 121p to each other. For example, an uppermost layer of interconnection layer 112 may also be implemented to include a plurality of interconnection pads, and the plurality of bumps 130 may be connected to and/or fixed to a space or region between the plurality of interconnection pads of the uppermost interconnection layer 112 and the plurality of pads 121p. The plurality of bumps 130 may be, for example, arranged in a central region (FCB_region) of the lower surface of the semiconductor chip 120, and a size (for example, horizontal area) of the central region (FCB_region) may be smaller than a size of the lower surface of the semiconductor chip 120, but example embodiments are not limited thereto.

A size of any or each of the plurality of chip bumps 130 may be smaller than a size of each of the plurality of package bumps 160. Any or each of the plurality of chip bumps 130 and the plurality of package bumps 160 may include, for example, a metal (for example, lead (Pb), bismuth (Bi), tin (Sn), and an alloy (Sn—Ag—Cu) including tin (Sn)) having a low melting point (a melting point lower than a melting point of a metal included in the interconnection layer 112 and the peripheral connection portion 145), but the present inventive concepts are not limited thereto. Any or each of the chip bumps 130 and the package bumps 160 may be, for example, in the form of a ball or pillar, and may be formed of a single layer or multiple layers. For example, each of the chip bumps 130 and the package bumps 160 may be a solder ball, but example embodiments are not limited thereto. At a temperature higher than the melting point, the plurality of chip bumps 130 and the plurality of package bumps 160 may be in a fluid state, using, for example, a reflow process and/or a thermal compression bonding (TCB) process. Thereafter, with a decrease in temperature, the plurality of chip bumps 130 and the plurality of package bumps 160 may be connected to and/or fixed to the plurality of interconnection pads of the interconnection layer 112.

The number of electrical paths provided by the semiconductor chip 120 may increase as the number of bumps 130 increases. As size(s) of any or each of the plurality of bumps 130 or distance(s) between the plurality of bumps 130 decreases, the number (or a degree of integration) of electrical paths, provided by the semiconductor chip 120, relative to a unit horizontal area of the semiconductor chip 120 may increase. A minimum size of each of the plurality of bumps 130 or a minimum distance between the plurality of bumps 130 may be desired or be determined in advance to ensure or increase reliability (for example, performance to prevent disconnection of an electrical connection path and occurrence of a short circuit in the electrical connection path) of the plurality of bumps 130. As a horizontal area of the semiconductor chip 120 increases, the number of bumps 130 may increase.

The semiconductor package 100a according to some example embodiments of the present inventive concepts may include a peripheral connection portion(s) 145, such that the peripheral connection portion 145 may be used as one or more additional electrical paths. Accordingly, the semiconductor package 100a may increase the number (or a degree of integration) of electrical paths, provided by the semiconductor chip 120, relative to a unit horizontal area of the semiconductor chip 120, thereby increasing the number of electrical paths, provided by the semiconductor chip 120, even without increasing a horizontal area of the semiconductor chip 120.

At least a portion of the peripheral pad portion 140 may be disposed on a side surface of the semiconductor chip 120, and the peripheral pad portion 140 may be electrically connected to the semiconductor chip 120 through (for example, by) a surface of the peripheral pad portion 140 opposing the semiconductor chip 120. The peripheral connection portion 145 may electrically connect the peripheral pad part 140 and the interconnection structure 110 to each other. A side surface of the semiconductor chip 120 may be, for example, a surface on which the plurality of chip bumps 130 are not disposed, such that the peripheral pad portion 140 and/or the peripheral connection portion 145 may have little effect on a degree of integration of the plurality of chip bumps 130, and may be used as additional electrical connection paths, provided by the semiconductor chip 120.

For example, the peripheral pad portion 140 may include, for example, at least one of copper (Cu), a copper alloy, aluminum (Al), and an aluminum alloy. The metal material is not, however, limited thereto, and may be implemented as at least one of nickel (Ni), gold (Au), cobalt (Co), tantalum (Ta), tellurium (Te), titanium (Ti), tungsten (W), and any alloys thereof (for example, TiN and TaN). For example, the peripheral pad portion 140 may include a plurality of peripheral pads arranged to surround or at least partially surround the semiconductor chip 120, but example embodiments are not limited thereto.

For example, the peripheral pad portion 140 may include a first peripheral pad portion 141 disposed on the lower surface of the semiconductor chip 120, and a second peripheral pad portion 142 disposed on the side surface of the semiconductor chip 120. The first and second peripheral pad portions 141 and 142 may be connected to each other. The peripheral connection portion 145 may extend from the first peripheral pad portion 141 or the second peripheral pad portion 142 to the interconnection structure 110.

For example, the first peripheral pad portion 141 may include a plurality of first peripheral pads arranged to surround the plurality of pads 121p, and the second peripheral pad portion 142 may include a plurality of second peripheral pads arranged to surround the device layer 122, but example embodiments are not limited thereto. The plurality of first peripheral pads and the plurality of second peripheral pads may be connected to each other, and may have, for example, a curved shape to surround or at least partially surround an edge of the semiconductor chip 120. Any or each of the plurality of first peripheral pads and the plurality of second peripheral pads may have, for example, a polygonal or circular shape, but example embodiments are not limited thereto.

A portion of the chip interconnection layer 122w of the device layer 122 may be electrically connected to the plurality of pads 121p through the chip interconnection vias 122v, and another portion of the chip interconnection layer 122w may be exposed to the side surface of the semiconductor chip 120 to be electrically connected to the peripheral connection portion 145. The peripheral pad portion 140 may be electrically connected between another portion of the chip interconnection layer 122w and the peripheral connection portion 145. Accordingly, the semiconductor package 100a according to some example embodiments of the present inventive concepts may use the peripheral connection portion(s) 145 as additional electrical paths, and may increase the number (or a degree of integration) of the plurality of electrical paths, provided by the semiconductor chip 120, relative to the unit horizontal area of the semiconductor chip 120, thereby increasing the number of electrical paths, even without increasing the horizontal area of the semiconductor chip 120.

For example, an upper end of the peripheral connection portion 145 may be connected to the peripheral pad portion 140, and a lower end of the peripheral connection portion 145 may be connected to the plurality of interconnection pads of the uppermost interconnection layer 112. The peripheral connection portion 145 may include a plurality of peripheral connection wirings arranged to surround or at least partially surround the plurality of bumps 130. For example, the plurality of peripheral connection wirings of the peripheral connection portion 145 may be, for example, formed using a patterning method the same as, substantially the same as, or similar to a method used for the interconnection layer 112. The patterning method may include, for example, a method of forming a photoresist layer, removing portions of the photoresist layer corresponding to the plurality of peripheral connection wirings, and filling the portions with a conductive material or plating the portions, but example embodiments are not limited thereto. For example, the conductive material, included in the peripheral connection portion 145, may include copper (Cu), aluminum (Al), silver (Ag), tin (Sn), gold (Au), nickel (Ni), lead (Pb), titanium (Ti), or any alloys thereof.

For example, a direction in which each of the plurality of peripheral connection wirings of the peripheral connection portion 145 extends may be inclined with respect to a vertical direction (for example, a Z-direction). For example, a direction in which the peripheral connection portion 145 extends from the peripheral pad portion 140 to the interconnection structure 110 may be inclined with respect to the vertical direction (for example, a Z-direction). For example, the peripheral connection portion 145 may be disposed such that at least a portion of the peripheral connection portion 145 does not vertically overlap the semiconductor chip 120. For example, separation distances MG1 and MG2 between a bump disposed to closest to the peripheral connection portion 145, among the plurality of bumps 130, and the peripheral connection portion 145 may be longer than separation distances D1 and D2 between the plurality of bumps 130. For example, the separation distances MG1 and MG2 may be equal to or about greater than 100 μm and less than 300 μm, and the separation distances D1 and D2 may about be 100 μm or less, but the present inventive concepts are not limited thereto.

Accordingly, the semiconductor package 100a may have a structure that is more advantageous for ensuring or improving reliability of the plurality of bumps 130 while (for example, during) forming the peripheral connection portion 145, or a structure that is more advantageous for ensuring and/or increasing a degree of integration of an interconnection line and/or reliability (for example, performance to reduce or prevent disconnection of the plurality of peripheral connection wirings and/or occurrence of a short circuit in the plurality of peripheral connection wirings) of the peripheral connection portion 145.

Referring to FIGS. 1A and 2A, the semiconductor package 100a according to some example embodiments of the present inventive concepts may further include at least one of an underfill portion 135, an encapsulant 150, and a plurality of package bumps 160.

The underfill portion 135 may be disposed between the interconnection structure 110 and the semiconductor chip 120, and may surround the plurality of bumps 130, and may be surrounded or at least partially surrounded by the peripheral connection portion 145. For example, the underfill portion 135 may include, for example, a non-conductive polymer, for example, non-conductive paste (NCP), but the present inventive concepts are not limited thereto. For example, the underfill portion 135 may include for example, at least one of an epoxy resin, silica (SiO₂), and an acrylic copolymer, or combinations thereof. The underfill portion 135 may be formed on the lower surface of the semiconductor chip 120 or the upper surface of the interconnection structure 110 during, for example, a reflow process and/or a TCB process, and may then fill a space between the semiconductor chip 120 and the interconnection structure 110. Depending on a design thereof, the underfill portion 135 may or may not protrude in a horizontal direction, and a protruding portion of the underfill portion 135 may or may not vertically overlap with the semiconductor chip 120.

A surface of the underfill portion 135 (for example, a surface of the protruding portion in the horizontal direction) may, for example, provide a placement surface for the peripheral connection portion 145. The peripheral connection portion 145 may be disposed and at least partially extend along the surface of the underfill portion 135. Additionally, or alternatively, the peripheral connection portion 145 may extend from a position thereof, lower than that of the upper surface of the semiconductor chip 120, to the interconnection structure 110 along the surface of the underfill portion 135 to electrically connect the semiconductor chip 120 and the interconnection structure 110 to each other. Accordingly, the semiconductor package 100a according to some example embodiments of the present inventive concepts may use the peripheral connection portion 145 as additional electrical paths, and may increase the number (or a degree of integration) of electrical paths, provided by the semiconductor chip 120, relative to a unit horizontal area of the semiconductor chip 120, thereby increasing the number of electrical paths, even without increasing a horizontal area of the semiconductor chip 120.

The encapsulant 150 may be disposed above the interconnection structure 110 to encapsulate or at least partially encapsulate the semiconductor chip 120. The peripheral connection portion 145 may be disposed between the underfill portion 135 and the encapsulant 150. The peripheral connection portion 145 may be in contact, for example direct contact, with each or either of the underfill portion 135 and the encapsulant 150. For example, when the peripheral connection portion 145 is implemented to include a plurality of peripheral connection wirings, a portion of the encapsulant 150 may be inserted between the plurality of peripheral connection wirings. Accordingly, the encapsulant 150 may further improve electrical reliability of the peripheral connection portion 145.

For example, the encapsulant 150 may be disposed to cover one or more side surfaces and an upper surface of the semiconductor chip 120, and may be in contact, for example direct contact, with side and upper surfaces of the semiconductor chip 120, but the present inventive concepts are not limited thereto. The encapsulant 150 may include a molding material such as an epoxy molding compound (EMC), but the present inventive concepts are not limited thereto. For example, the encapsulant 150 may include one or more insulating material(s), such as a thermosetting resin such as an epoxy resin, a thermoplastic resin such as polyimide, a prepreg including an inorganic filler and/or a glass fiber, an ABF, FR-4, BT, and/or PID, but example embodiments are not limited thereto.

The plurality of package bumps 160 may be electrically connected to a lowermost interconnection layer 112 (for example, a lowermost layer of the interconnection layer 112), and may be disposed in upper and/or lower passages of the lower solder mask layer 116 on a lower surface of the interconnection structure 110. The plurality of package bumps 160 may physically and/or electrically connect the semiconductor package 100a to an external device such as a main board, and/or may be electrically connected to an additional semiconductor package below the semiconductor package 100a, but example embodiments are not limited thereto.

Referring to FIG. 1B, a peripheral pad portion 140 of a semiconductor package 100b according to some example embodiments of the present inventive concepts may include a first peripheral pad portion 141, but may not include the second peripheral pad portion 142 of FIG. 1A. In addition, a chip interconnection layer 122w of a device layer 122 may not, for example, be exposed to a side surface of a semiconductor chip 120, and may be connected to the peripheral pad portion 140 through chip interconnection vias 122v in the vicinity of an edge of the semiconductor chip 120, but example embodiments are not limited thereto. A peripheral connection portion 145 may extend from a position thereof, lower than that of an upper surface of the semiconductor chip 120 to an interconnection structure 110 along a surface of an underfill portion 135 to electrically connect the semiconductor chip 120 and the interconnection structure 110 to each other.

Referring to FIG. 1C, a peripheral pad portion 140 of a semiconductor package 100c according to some example embodiments of the present inventive concepts may include a second peripheral pad portion 142, but may not include the first peripheral pad portion 141 of FIG. 1A. In addition, a portion of the underfill portion 135 may be positioned to be higher than a lower surface of a semiconductor chip 120 to be in contact with the second peripheral pad portion 142, but example embodiments are not limited thereto. A chip interconnection layer 122w may, for example, be exposed to a side surface of the semiconductor chip 120 to be electrically connected to a peripheral connection portion 145, but example embodiments are not limited thereto.

Referring to FIG. 1D, a chip interconnection layer 122w of a device layer 122 of a semiconductor package 100d according to some example embodiments of the present inventive concepts may not be exposed to a side surface of a semiconductor chip 120, and an element layer 123d of a semiconductor substrate 123 may be exposed to the side surface of the semiconductor chip 120. A peripheral pad portion 140 may be between (and, for example, connect or directly connect) the element layer 123d and a peripheral connection portion 145.

Referring to FIG. 2B, a peripheral connection portion 145 of a semiconductor package 100e according to some example embodiments of the present inventive concepts may further include at least one of a ground connection portion 145gr configured to provide a ground, and a DC voltage connection portion 145dc configured to provide a DC voltage. A peripheral pad portion 140 may further include at least one of a ground pad portion 140gr configured to provide a ground, and a DC voltage pad portion 140dc configured to provide a DC voltage, but example embodiments are not limited thereto. For example, any or each of the ground connection portion 145gr and the DC voltage connection portion 145dc may have a width thicker than a line width of a chip interconnection layer 122w, and may be in the form of, for example, a curved plate, but example embodiments are not limited thereto.

Referring to FIG. 2C, a peripheral connection portion 145 of a semiconductor package 100f according to some example embodiments of the present inventive concepts may have a width thicker than a line width of a chip interconnection layer 122w, and may be in the form of a curved plate. The peripheral pad portion 140 may, surround (for example, entirely surround or at least partially surround) a semiconductor chip 120. A form of the peripheral connection portion 145 is not limited to a form in which the plurality of peripheral connection wirings, illustrated in FIG. 2A, are arranged, and a form of the peripheral pad portion 140 also is not limited to the form in which the plurality of peripheral pads, illustrated in FIG. 2A, are arranged.

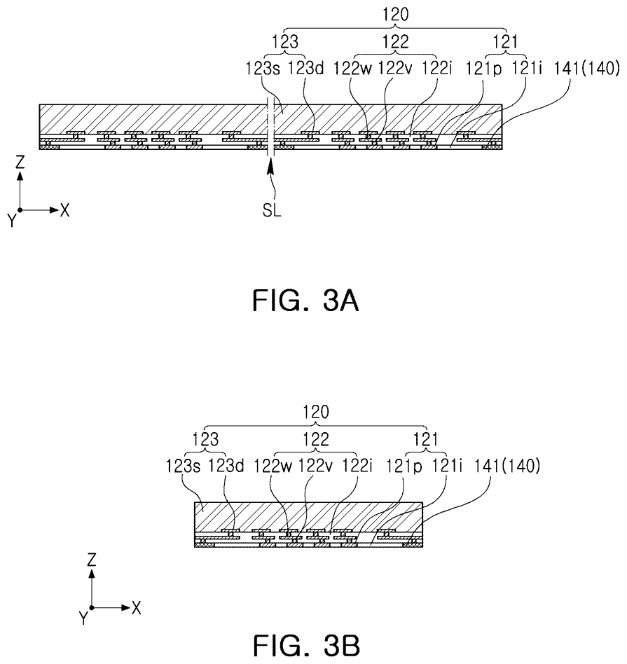

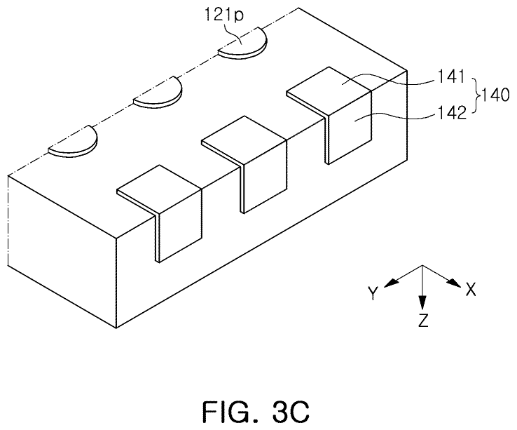

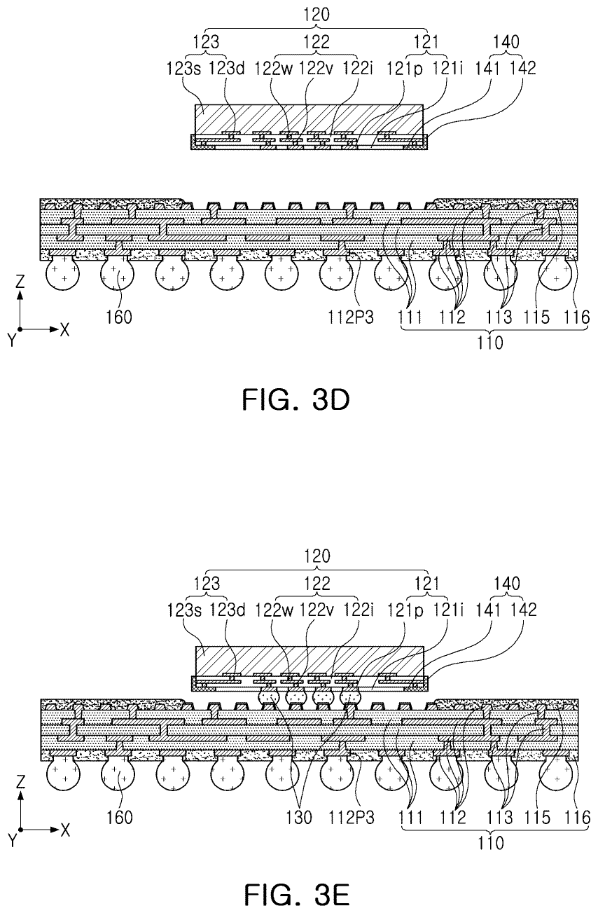

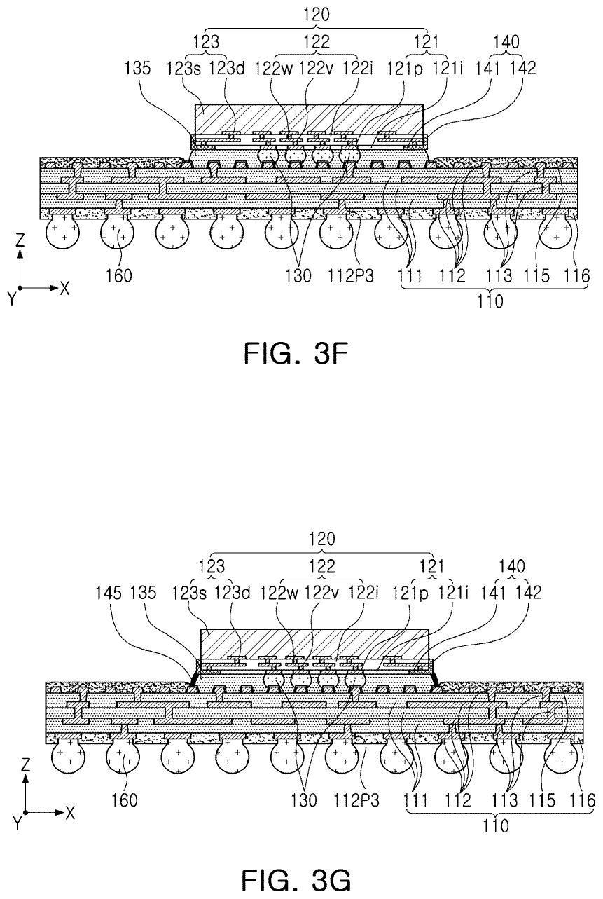

FIGS. 3A to 3G sequentially illustrate a method of manufacturing the semiconductor package 100a illustrated in FIG. 1A, but methods of manufacturing the semiconductor package 100a according to example embodiments of the present inventive concepts are not limited to FIGS. 3A to 3G, the operations illustrated thereby.

Referring to FIGS. 3A and 3B, a plurality of semiconductor chips 120 may be formed by dicing a semiconductor wafer (including a pad layer 121, a device layer 122, and a semiconductor substrate 123) in a vertical direction along a scribe lane region SL. In such a case, a chip interconnection layer 122w of a device layer 122 may also be cut by dicing. A cut portion of the interconnection layer 122w may be a portion exposed through a side surface of each of the plurality of semiconductor chips 120.

Referring to FIG. 3C, a peripheral pad portion 140 may be formed to have a curved shape so as to surround or at least partially surround an edge between a lower surface and an upper surface of the semiconductor chip 120. Referring to FIG. 3D, the semiconductor chip 120 may move to (for example, be positioned at or on) an upper side (for example, surface) of an interconnection structure 110. For example, the semiconductor chip 120 may be moved by pick and place equipment, but example embodiments are not limited thereto.

Referring to FIG. 3E, a plurality of bumps 130 may be formed between the semiconductor chip 120 and the interconnection structure 110. In this case, for example, a reflow process and/or a TCB process may be performed, but example embodiments are not limited thereto. Referring to FIG. 3F, an underfill portion 135 may be disposed (for example, coated) between the semiconductor chip 120 and the interconnection structure 110. Referring to FIG. 3G, a peripheral connection portion 145 may be formed along a surface of the underfill portion 135. Thereafter, the encapsulant 150 of FIG. 1A may be formed.

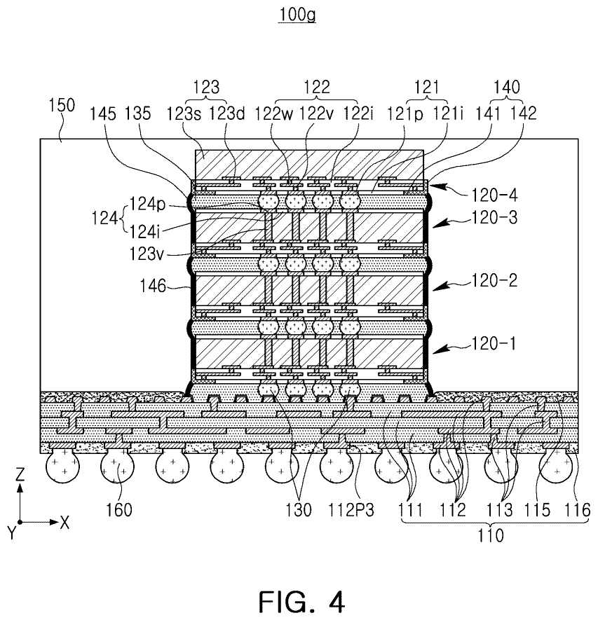

Referring to FIG. 4, a semiconductor chip of a semiconductor package 100g according to some example embodiments of the present inventive concepts may be or include a plurality of semiconductor chips 120-1, 120-2, 120-3, and 120-4 vertically overlapping or at least partially overlapping with each other. For example, the semiconductor chip 120-1 may be or include a controller chip and/or a buffer chip, and each of the plurality of semiconductor chips 120-2, 120-3, and 120-4 may be or include a memory chip. However, the present inventive concepts are not limited thereto. For example, any or each of the plurality of semiconductor chips 120-1, 120-2, and 120-3 may further include a rear pad layer 124, and the semiconductor substrate 123 may further include through-electrodes 123v.

Each of the through-electrodes 123v may have, for example, a pillar structure passing through the semiconductor substrate 123, but example embodiments are not limited thereto. For example, upper ends of the through-electrodes 123v may be connected to a plurality of rear pads 124p, and lower ends of the through-electrodes 123v may be connected to an element layer 123d and/or a chip interconnection layer 122w. For example, the through-electrodes 123v may include a via plug and/or an insulating liner surrounding the via plug. The rear pad layer 124 may be, for example, implemented in a same or substantially same manner as a pad layer 121, and the plurality of rear pads 124p and a rear passivation layer 124i may also be implemented in a same or substantially same manner (for example, a structure, a material, and/or a process) as a plurality of pads 121p and a passivation layer 121i.

The peripheral connection portion 145 may electrically connect the interconnection structure 110 to a side surface of at least one of the plurality of semiconductor chips 120-1, 120-2, 120-3, and 120-4. Accordingly, the semiconductor package 100g according to some example embodiments of the present inventive concepts may use as additional electrical paths, and may increase the number (or a degree of integration) of electrical paths, provided by the plurality of semiconductor chips 120-1, 120-2, 120-3, and 120-4, relative to a unit horizontal area of the plurality of semiconductor chips 120-1, 120-2, 120-3, and 120-4, thereby increasing the number of electrical paths, even without increasing a horizontal area of the plurality of semiconductor chips 120-1, 120-2, 120-3, and 120-4.

For example, a plurality of peripheral connection portions 145 may be formed along surfaces of one or more a plurality of underfill portions 135 between ones of the plurality of semiconductor chips 120-1, 120-2, 120-3, and 120-4, and may be connected to each other through a plurality of side connection portions 146 respectively disposed on side surfaces of the plurality of semiconductor chips 120-1, 120-2, 120-3, and/or 120-4. The plurality of peripheral connection portions 145 may be respectively connected to side surfaces of different semiconductor chips of the plurality of semiconductor chips 120-1, 120-2, 120-3, and/or 120-4, and any or each of the side connection portions 146 may be respectively electrically connected to a region between ones of peripheral connection portions 145. For example, the plurality of side connection portions 146 may be implemented as a plurality of side connection wirings extending vertically, and may be implemented in a similar manner to the plurality of peripheral connection portions 145.

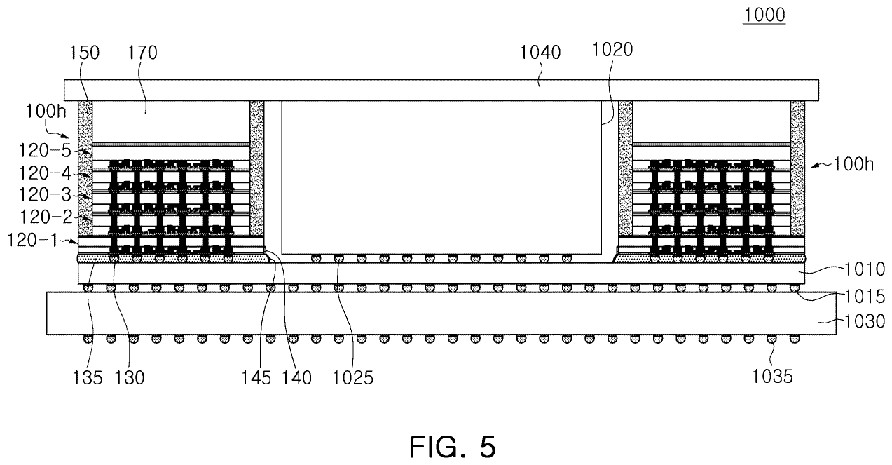

Referring to FIG. 5, a semiconductor package 1000 according to some example embodiments of the present inventive concepts may include a plurality of semiconductor packages 100h according to some example embodiments of the present inventive concepts. Each of the plurality of semiconductor packages 100h may be implemented in a similar manner to the semiconductor package 100g of FIG. 4. For example, the semiconductor package 1000 may be, for example, a high-bandwidth memory (HBM), but the present inventive concepts is not limited thereto.

Unlike the semiconductor package 100g of FIG. 4, each of the plurality of semiconductor packages 100h of FIG. 5 may not include the plurality of side connection portions 146 of FIG. 4. A peripheral connection portion 145 of each of the plurality of semiconductor packages 100h may not, for example, be disposed on side surfaces of a plurality of semiconductor chips 120-2, 120-3, 120-4, and 120-5, and may electrically connect a side surface of a semiconductor chip 120-1 and an interconnection structure 1010 to each other.

Unlike the semiconductor package 100g of FIG. 4, each of the plurality of semiconductor packages 100h of FIG. 5 may further include an upper dummy chip 170 disposed above a plurality of semiconductor chips 120-1, 120-2, 120-3, 120-4, and 120-5. For example, the upper dummy chip 170 may include, for example, at least one semiconductor material such as, for example, silicon, and a substrate, such as, for example, a metal. In some example embodiments, the upper dummy chip 170 may provide a heat dissipation function and/or an identification mark display region.

Unlike the semiconductor package 100g of FIG. 4, each of the plurality of semiconductor packages 100h of FIG. 5 may have a structure in which an underfill portion 135 is not disposed between the plurality of semiconductor chips 120-1, 120-2, 120-3, 120-4, and 120-5. For example, the plurality of semiconductor chips 120-1, 120-2, 120-3, 120-4, and 120-5 may have a bonding structure (for example, a direct bonding structure) in which a plurality of pads and a plurality of interconnection pads (or a plurality of rear pads) are in contact (for example, direct contact) with each other, or may have a hybrid bonding structure in which, for example, a passivation layer and a rear passivation layer are in contact (for example, direct contact) with each other, but example embodiments are not limited thereto.

Referring to FIG. 5, the semiconductor package 1000 according to some example embodiments of the present inventive concepts may further include at least one of an interconnection structure 1010, a controller chip 1020, a package substrate 1030, and a heat dissipation member 1040.

The controller chip 1020 may be mounted through (for example, on or by) a package bump 1025 on a central region of the interconnection structure 1010, and the plurality of semiconductor packages 100h may be arranged to surround or at least partially surround the controller chip 1020. The controller chip 1020 may, for example, transmit a signal for controlling the plurality of semiconductor packages 100h to the plurality of semiconductor packages 100h through (for example, by) the interconnection structure 1010, and the plurality of semiconductor packages 100h may also transmit a signal to the controller chip 1020 through (for example, by) the interconnection structure 1010.

The interconnection structure 1010 may be mounted on an upper surface of the package substrate 1030 through the package bump 1015. A package bump 1035 may be disposed on a lower surface of the package substrate 1030. For example, the package substrate 1030 may be implemented as, for example, a printed circuit board, and the interconnection structure 1010 may be defined as an interposer.

The heat dissipation member 1040 may be disposed on an upper surface of the controller chip 1020 and/or of the plurality of semiconductor packages 100h. For example, the heat dissipation member 1040 may include for example, a heat slug, and may include, for example, at least material (for example, gold (Au), silver (Ag), copper (Cu), iron (Fe), graphite, or graphene) having thermal conductivity higher than that of air, and may be in contact (for example, direct contact) with the upper surfaces of the controller chip 1020 and/or the plurality of semiconductor packages 100h through, for example, a thermal interface material (TIM) layer, but example embodiments are not limited thereto.

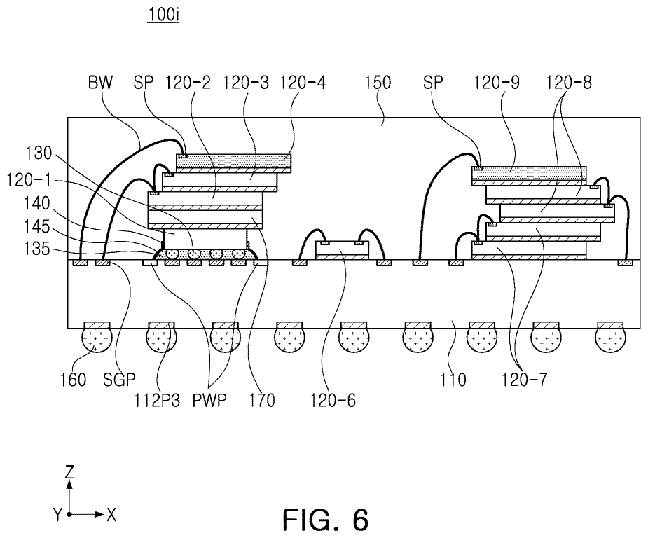

Referring to FIG. 6, a semiconductor package 100i according to some example embodiments of the present inventive concepts may further include a plurality of conductive wires BW at least electrically connecting an upper surface of an uppermost semiconductor chip 120-4, among a plurality of semiconductor chips 120-1, 120-2, 120-3, and 120-4, to an interconnection structure 110.

For example, one end of each of the conductive wires BW may be electrically connected to one of signal pads SP, and another end of each of conductive wires BW may be, correspondingly, electrically connected to a plurality of interconnection pads SGP and PWP of the interconnection structure 110. Each of the conductive wires BW may, for example include a highly conductive metal material such as, for example, gold (Au), aluminum (Al), or copper (Cu), but example embodiments are not limited thereto.

In addition to the plurality of semiconductor chips 120-1, 120-2, 120-3, and 120-4, a plurality of semiconductor chips 120-6, 120-7, 120-8, and 120-9 may also be disposed above the interconnection structure 110. The plurality of semiconductor chips 120-6, 120-7, 120-8, and 120-9 may be electrically connected to the interconnection structure 110 through the conductive wires BW without a plurality of bumps.

According to some example embodiments of the present inventive concepts, a semiconductor package may efficiently increase the number of electrical connection paths that may be provided by a semiconductor chip. For example, according to some example embodiments of the present inventive concepts, the number of electrical connection paths of the semiconductor chip may increase even without increasing a size of the semiconductor chip or a degree of integration of the electrical connection paths of the semiconductor chip. For example, according to some example embodiments of the present inventive concepts, the number of electrical connection paths of the semiconductor chip may increase even without increasing the size of the semiconductor package and/or manufacturing costs for improving the degree of integration. For example, according to some example embodiments of the present inventive concepts, it may be efficient to add more electrical connection paths without compromising or substantially compromising reliability of the plurality of bumps in a state in which an arrangement of the plurality of bumps is already determined.

While example embodiments have been shown and described above, it will be apparent to those ordinarily skilled in the art that modifications and variations could be made without departing from the spirit and scope of the present inventive concepts as in the appended claims.

Terms, such as first, second, etc. may be used herein to describe various elements, but these elements should not be limited by these terms. The above terms are used only for the purpose of distinguishing one component from another. For example, a first element may be termed a second element, and, similarly, a second element may be termed a first element, without departing from the scope of the present disclosure.

Singular expressions may include plural expressions unless the context clearly indicates otherwise. Terms, such as “include” or “has” may be interpreted as adding features, numbers, steps, operations, components, parts, or combinations thereof described in the specification.

It will be understood that when an element or layer is referred to as being “on”, “connected to”, “coupled to”, “attached to”, or “in contact with” another element or layer, it can be directly on, connected to, coupled to, attached to, or in contact with the other element or layer, or intervening elements or layers may be present. In contrast, when an element is referred to as being “directly on”, “directly connected to”, “directly coupled to”, “directly attached to”, or “in direct contact with” another element or layer, there are no intervening elements or layers present. As used herein, the term “and/or” includes any and all combinations of one or more of the associated listed items.

When the terms “about” or “substantially” are used in this specification in connection with a numerical value, it is intended that the associated numerical value includes a manufacturing or operational tolerance (e.g., ±10%) around the stated numerical value. Moreover, when the words “generally” and “substantially” are used in connection with geometric shapes, it is intended that precision of the geometric shape is not required but that latitude for the shape is within the scope of the disclosure. Further, regardless of whether numerical values or shapes are modified as “about” or “substantially,” it will be understood that these values and shapes should be construed as including a manufacturing or operational tolerance (e.g., ±10%) around the stated numerical values or shapes. When ranges are specified, the range includes all values therebetween such as increments of 0.1%.

It will be understood that elements and/or properties thereof may be recited herein as being “the same” or “equal” as other elements, and it will be further understood that elements and/or properties thereof recited herein as being “identical” to, “the same” as, or “equal” to other elements may be “identical” to, “the same” as, or “equal” to or “substantially identical” to, “substantially the same” as or “substantially equal” to the other elements and/or properties thereof. Elements and/or properties thereof that are “substantially identical” to, “substantially the same” as or “substantially equal” to other elements and/or properties thereof will be understood to include elements and/or properties thereof that are identical to, the same as, or equal to the other elements and/or properties thereof within manufacturing tolerances and/or material tolerances. Elements and/or properties thereof that are identical or substantially identical to and/or the same or substantially the same as other elements and/or properties thereof may be structurally the same or substantially the same, functionally the same or substantially the same, and/or compositionally the same or substantially the same.

Spatially relative terms (e.g., “beneath,” “below,” “lower,” “above,” “upper,” and the like) may be used herein for ease of description to describe one element or feature's relationship to another element(s) or feature(s) as illustrated in the figures. It should be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the term “below” may encompass both an orientation of above and below. The device may be otherwise oriented (rotated 90 degrees or at other at other orientations) and the spatially relative descriptors used herein interpreted accordingly.

What is claimed is:

1. A semiconductor package comprising:
an interconnection structure in which at least one insulating layer and at least one interconnection layer are alternately stacked;
a semiconductor chip including a plurality of pads, the semiconductor chip at least partially overlapping with the interconnection structure in the vertical direction;
a plurality of bumps between the plurality of pads and the interconnection structure;
a peripheral pad portion at least a portion of which is on a side surface of the semiconductor chip, the peripheral pad portion being electrically connected to the semiconductor chip by a surface thereof that is opposing the semiconductor chip; and
a peripheral connection portion electrically connecting the peripheral pad portion and the interconnection structure to each other.

2. The semiconductor package of claim 1, further comprising:
an underfill portion between the interconnection structure and the semiconductor chip, the underfill portion at least partially surrounding the plurality of bumps,
wherein the peripheral connection portion at least partially extends along a surface of the underfill portion.

3. The semiconductor package of claim 2, further comprising:
an encapsulant above the interconnection structure and at least partially encapsulating the semiconductor chip,
wherein the peripheral connection portion is between the underfill portion and the encapsulant.

4. The semiconductor package of claim 3, wherein the peripheral connection portion is in contact with the underfill portion and with the encapsulant.

5. The semiconductor package of claim 1, wherein
the peripheral pad portion includes
a first peripheral pad portion on a lower surface of the semiconductor chip; and
a second peripheral pad portion on the side surface of the semiconductor chip, and
the first and second peripheral pad portions are connected to each other.

6. The semiconductor package of claim 1, wherein
the peripheral pad portion includes a plurality of peripheral pads, the plurality of peripheral pads at least partially surrounding the semiconductor chip, and
the peripheral connection portion includes a plurality of peripheral connection wirings, the plurality of peripheral wirings at least partially surrounding the plurality of bumps.

7. The semiconductor package of claim 1, wherein a direction in which the peripheral connection portion extends from the peripheral pad portion to the interconnection structure is oblique with respect to a vertical direction.

8. The semiconductor package of claim 1, wherein at least a portion of the peripheral connection portion is configured to provide at least one of a ground or DC voltage.

9. The semiconductor package of claim 1, wherein at least a portion of the peripheral connection portion does not vertically overlap with the semiconductor chip.

10. The semiconductor package of claim 1, wherein a separation distance between the peripheral connection portion and a bump closest to the peripheral connection portion, among the plurality of bumps, is longer than a separation distance between the plurality of bumps.

11. The semiconductor package of claim 1, wherein a melting point of the peripheral connection portion is higher than a melting point of any of the plurality of bumps.

12. The semiconductor package of claim 1, wherein the semiconductor chip includes:
a semiconductor substrate above the plurality of pads; and
a device layer between the plurality of pads and the semiconductor substrate,
wherein the device layer includes a chip interconnection layer having a portion electrically connected to the plurality of pads, and
another portion of the chip interconnection layer is exposed to the side surface of the semiconductor chip and is electrically connected to the peripheral connection portion.

13. The semiconductor package of claim 1, wherein
the semiconductor chip includes a plurality of semiconductor chips at least partially overlapping with each other in the vertical direction, and
the peripheral connection portion electrically connects a side surface of at least one of the plurality of semiconductor chips and the interconnection structure to each other.

14. The semiconductor package of claim 13, further comprising:
a side connection portion disposed on a side surface of at least one of the plurality of semiconductor chips,
wherein the peripheral connection portion includes a plurality of peripheral connection portions respectively connected to side surfaces of different semiconductor chips of the plurality of semiconductor chips, and
the side connection portion is electrically connected to the plurality of peripheral connection portions.

15. The semiconductor package of claim 13, further comprising:
a plurality of conductive wires electrically connecting at least an upper surface of an uppermost semiconductor chip, among the plurality of semiconductor chips, to the interconnection structure.

16. A semiconductor package comprising:
an interconnection structure in which at least one insulating layer and at least one interconnection layer are alternately stacked;
a semiconductor chip including a plurality of pads, the semiconductor chip at least partially overlapping with the interconnection structure in a vertical direction;
a plurality of bumps between the plurality of pads and the interconnection structure;
an underfill portion between the interconnection structure and the semiconductor chip, the underfill portion at least partially surrounding the plurality of bumps; and
a peripheral connection portion
extending along a surface of the underfill portion and from a position lower than that of an upper surface of the semiconductor chip to the interconnection structure,
and electrically connecting the semiconductor chip and the interconnection structure to each other.

17. The semiconductor package of claim 16, further comprising:
a first peripheral pad portion on a lower surface of the semiconductor chip; and
a second peripheral pad portion on a side surface of the semiconductor chip,
wherein the first and second peripheral pad portions are connected to each other, and
the peripheral connection portion extends from the first peripheral pad portion or from the second peripheral pad portion to the interconnection structure.

18. The semiconductor package of claim 16, wherein
the peripheral connection portion includes a plurality of peripheral connection wirings at least partially surrounding the plurality of bumps, and
a direction in which each of the plurality of peripheral connection wirings extends is oblique with respect to a vertical direction.

19. A semiconductor package comprising:
an interconnection structure in which at least one insulating layer and at least one interconnection layer are alternately stacked;
a semiconductor chip including a plurality of pads, the semiconductor chip at least partially overlapping with the interconnection structure in a vertical direction;
a plurality of bumps between the plurality of pads and the interconnection structure;
a peripheral connection portion at least partially surrounding the plurality of bumps,
wherein the semiconductor chip includes
a semiconductor substrate above the plurality of pads; and
a device layer between the plurality of pads and the semiconductor substrate,
wherein the device layer includes a chip interconnection layer having a portion electrically connected to the plurality of pads, and
another portion of the chip interconnection layer is exposed to a side surface of the semiconductor chip and is electrically connected to the peripheral connection portion.

20. The semiconductor package of claim 19, further comprising:
a peripheral pad portion electrically connected to the another portion of the chip interconnection layer and to the peripheral connection portion; and
an underfill portion at least partially surrounded by the peripheral connection portion, the underfill portion at least partially surrounding the plurality of bumps.
